(19) United States
(12) Patent Application Publication
(10) Pub. No.: US 2008/0138986 A1
(43) Pub. Date: Jun. 12, 2008

(54) MASK LAYER TRIM METHOD USING CHARGED PARTICLE BEAM EXPOSURE

(75) Inventors: Lin Zhou, LaGrangeville, NY (US); Eric Peter Solecky, Hyde Park, NY (US); James E. Doran, Essex Junction, VT (US)

Correspondence Address: SCULLY, SCOTT, MURPHY & PRESSER, P.C., 400 GARDEN CITY PLAZA, Suite 300, GARDEN CITY, NY, 11530, US

(73) Assignee: INTERNATIONAL BUSINESS MACHINES CORPORATION, Armonk, NY (US)

(21) Appl. No.: 11/567,360

(22) Filed: Dec. 6, 2006

(51) Int. Cl. H01L 21/302

(52) U.S. Cl. 438/690; 257/E21.214

(57) ABSTRACT

A method for forming a patterned target layer over a substrate uses a blanket target layer located over the substrate and a patterned mask layer located over the blanket target layer At least one mask layer pattern wit the patterned mask layer is treated with a charged particle beam to provide a dimensionally changed mask layer pattern within a dimensionally changed mask. The dimensionally changed mask is used as an etch mask when etching the blanket target layer to form the patterned target layer.

### BACKGROUND

1. Field of the Invention

The invention relates generally to methods for fabricating semiconductor structures. More particularly, the invention relates to methods for fabricating semiconductor structures with enhanced flexibility.

2. Description of the Related Art

Semiconductor structures typically comprise patterned layers that may in turn comprise conductor materials, semiconductor materials and/or dielectric materials. The patterned layers may be formed using generally conventional photolithographic and etch methods. Such generally conventional photolithographic and etch methods typically include forming a blanket photdresist layer located over a blanket target layer in turn located over a substrate The blanket photoresist layer is then photoexposed and developed to form a patterned photoresist layer located over the blanket target layer. In turn, the patterned photoresist layer is used as an etch mask layer for forming a patterned target layer from the blanket target layer.

While conventional photolithographic and etch methods are quite common within the semiconductor structure fabrication art, conventional photolithographic and etch methods are nonetheless not entirely without problems within he semiconductor structure fabrication art. In particular, conventional photolithographic and etch methods may yield undesirable region-specific variations in dimension (i.e., in particular a critical dimension linewidth) of a patterned photoresist layer that is used as an etch mask layer. Such region-specific variations of dimension of the patterned photoresist layer may in turn yield region-specific variations of a corresponding patterned target layer that in turn may provide for compromised performance of a semiconductor device from which is comprised the patterned target layer.

Various methods for modifying or controlling dimensions when fabricating semiconductor structures are known in the semiconductor fabrication art.

Particular examples of methods are disclosed within: (1) Dakshina-Murthy et al., in U.S. Pat. No. 6,500,755 (a plasma ashing method for forming a reduced feature size patterned photoresist layer for use as an etch mask layer); (2)(a) Shields et al., in U.S. Pat. No. 6,630,288; (b) Okoroanyanwu et al., in U.S. Pat. No. 6,653,231; (c) Gabriel et al., in U.S. Pat. No. 6,716,571; and (d) Fisher et al., in U.S. Pat. No. 6,828,259 (a sequential electron beam treatment and plasma ashing method for forming a reduced feature size patterned photoresist layer for use as an etch mask layer); (3) Yang et al., in U.S. Pat. No. 6,790,782 (a plasma ashing method that uses a bottom anti-reflective coating (BARC) for forming a reduced feature size patterned photoresist layer for use as an etch mask layer); and (4)(a) Dalcshina-Murthy et al., in U.S. Pat. No. 6,900,139; and (b) Raebiger et al., in U.S. Pat. No. 7,041,434 (specific optical methods for endpoint detection and control when trimming a patterned photoresist layer for use as an etch mask-layer).

Additional particular examples of methods are disclosed within: (1) Livesay, in U.S. Pat. No. 5,468,595 (an electron beam treatment method for insolubilizing certain portions of a blanket photoresist layer when forming a patterned photoresist layer therefrom); (2) Wilbur et al., in U.S. Pat. No. 6,664,500 (a resistor trimming method that uses a laser having a particular output wavelength); (3) Patel et al., in U.S. Pat. No. 6,808,942 (a scatterometer method for determining a patterned photoresist layer trim time); (4) Mui et al., in U.S. Pat. No. 6,858,361 (a feed forward method for controlling a patterned photoresist layer critical dimension within the context of a photoresist trim process); and (5) Mui et al., in U.S. Pat. No. 6,924,088 (a patterned photoresist layer trim method that uses critical dimension measurements from isolated and dense patterns for purposes of considering microloading effects within the patterned photoresist layer trim method).

Control of semiconductor device and semiconductor structure dimensions is likely to be of considerable continued importance as semiconductor device dimensions and semiconductor structure dimensions continue to decrease. Thus, desirable are methods that provide for enhanced flexibility in fabricating semiconductor devices and semiconductor structures with enhanced dimensional control.

### SUMMARY OF THE INVENTION

The invention includes a method for forming a mask layer (i.e., typically a photoresist mask layer) that in turn may be used as an etch mask when forming a patterned target layer, such as a gate electrode, within a semiconductor structure. The method uses a charged particle beam, such as an electron beam, exposure of at least one mask layer pattern within the mask layer prior to using the mask layer as the etch mask layer.

A method for forming a patterned layer in accordance with the invention includes providing a substrate having a blanket target layer located thereover and a mask layer located over the blanket target layer. The method also includes treating at least one individual mask layer pattern within the mask layer with a charged particle beam to form at least one dimensionally changed mask layer pattern within a dimensionally changed mask layer. The method also includes etching the blanket target layer to form a patterned target layer while using the dimensionally changed mask layer as an etch mask.

Another method for forming a patterned layer in accordance with the invention includes providing a substrate having a blanket target layer located thereover and a mask layer located over the blanket target layer. This other method also includes treating separately at least two individual mask layer patterns within the mask layer with a focused charged particle beam to form at least two separate and differently dimensionally changed mask layer patterns within a dimensionally changed mask layer. Tis other method also includes etching the blanket target layer to form a patterned target layer while using the dimensionally changed mask layer as an etch mask.

### BRIEF DESCRIPTION OF THE DRAWINGS

The objects, features and advantages of the invention are understood within the context of the Description of the Preferred Embodiment as set forth below. The Description of the Preferred Embodiment is understood within the context of the accompanying drawings, which form a material part of this disclosure, wherein:

FIG. 1 to FIG. 5 show a series of schematic cross-sectional diagrams illustrating the results of progressive stages in fabricating a semiconductor structure in accordance with an embodiment of the invention.

FIG. 6 to FIG. 8 show a series of graphs correlating semiconductor structure dimensions with electron beam irradiation in accordance with an embodiment of the invention.

### DESCRIPTION OF THE PREFERRED EMBODIMENT

The invention, which includes a method for forming a patterned target layer, is described in further detail below within the context of the drawings described above. Since the drawings are intended for illustrative purposes, the drawings are not necessarily drawn to scale.

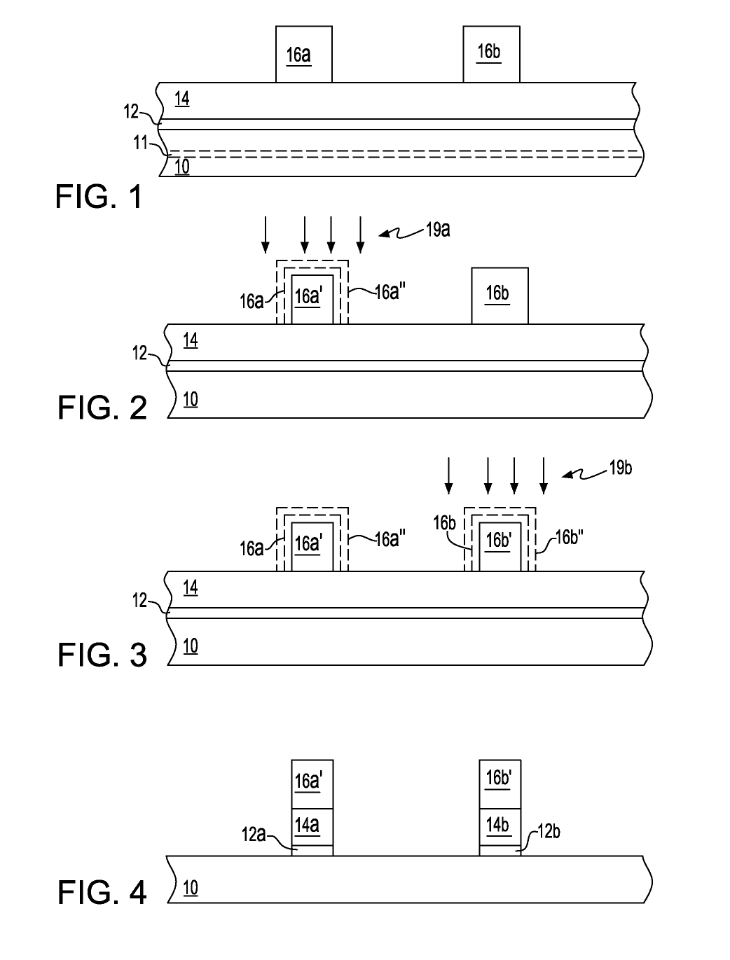

FIG. 1 to FIG. 5 show a series of schematic cross-sectional diagrams illustrating the results of progressive stages in fabricating a semiconductor structure in accordance with a particular embodiment of the invention. This particular embodiment comprises a preferred embodiment of the invention. FIG. 1 shows a schematic cross-sectional diagram of the semiconductor structure at an early stage in the fabrication thereof in accordance with the preferred embodiment.

FIG. 1 shows a semiconductor substrate 10 including an optional buried dielectric layer 1I located therein. A gate dielectric material layer 12 is located upon the semiconductor substrate 10 and a gate electrode material layer 14 is located upon the gate dielectric material layer 12. Finally, FIG. 1 also illustrates a plurality of mask layers 16 (i.e., mask layer patterns within a mask layer in accordance with the claimed invention) located laterally separated upon the gate electrode material layer 14.

Although the preferred embodiment illustrates the invention within the context of a semiconductor substrate 10 having a gate dielectric material layer 12 located thereupon and a gate electrode material layer 14 located thereover, the embodiment and the invention are not intended to be so limited. Rather, the embodiment also contemplates that any of several conductor substrates, semiconductor substrates or dielectric substrates may be substituted and used in place of the semiconductor substrate 10 (which absent the optional buried dielectric layer 11 is intended as a bulk semiconductor substrate and which present the optional buried dielectric layer 11 is intended as a semiconductor-on-insulator (SOI) substrate).

In addition, one of the gate dielectric material layer 12 and the gate electrode material layer 14 may also be optional within the invention. Under such circumstances the remaining one of the gate dielectric material layer 12 and the gate electrode material layer 14 may be generally designated as a blanket target layer. Such a blanket target layer may alternatively generally comprise a material selected from the group including but not limited to conductor materials, semiconductor materials and dielectric materials.

Commonly, the semiconductor substrate 10 comprises a semiconductor material. Non-limiting examples of candidate semiconductor materials include silicon, germanium, silicon-germanium alloy, silicon carbide, silicon-germanium carbide alloy and compound semiconductor materials (i.e., such as gallium arsenide, indium arsenide and indium phosphide semiconductor materials). Typically, the semiconductor substrate 10 has a thickness from about 0.5 to about 1.5 mm. The optional buried dielectric layer 11 will typically comprise an oxide, nitride or oxynitride of the base semiconductor material from which is comprised the semiconductor substrate 10. Other dielectric materials are not excluded. Typically, the optional buried dielectric layer has a thickness from about 1400 to about 1600 angstroms.

Commonly the gate dielectric material layer 12 comprises a gate dielectric material selected from the group including but not limited to generally lower dielectric constant gate dielectric materials (i.e., having a dielectric constant from about 4 to about 20) and generally higher dielectric constant gate dielectric materials (i.e., having a dielectric constant from about 20 to at least about 100). The former typically comprise oxides, nitrides and oxynitrides of silicon, although similar compounds comprising elements other than silicon are not excluded. The latter typically include heavier metal oxides and multiple metal oxides. Typically, the gate dielectric material layer 12 comprises a thermal silicon oxide gate dielectric material that has a thickness from about 10 to about 50 angstroms.

The gate electrode material layer 14 comprises a gate electrode material. Candidate gate electrode materials include certain metals, metal alloys, metal silicides and metal nitrides, as well as doped polysilicon (having a dopant concentration from about 1 e18 to about 1 e22 dopant atoms per cubic centimeter) and polycide (doped polysilicon/metal silicide stack) gate electrode materials. Typically, the gate electrode material layer has a thickness from about 100 to about 300 angstroms.

Finally, the mask layers 16a and 16b typically comprise a photoresist material, although the embodiment is not necessarily so limited. Non-limiting examples of candidate photoresist materials include positive photoresist materials, negative photoresist materials and hybrid photoresist materials. The mask layers 16a and 16b when comprising a photoresist material are formed incident to photoexposure and development of a blanket photoresist material layer. Photoexposure wavelengths for the blanket photoresist material layer may vary, but will typically include 157, 193, 248 and 365 nm photoexposure wavelengths. Typically, each of the mask layers 16a and 16b has a thickness from about 1500 to about 23000 angstroms and a linewidth from about 450 angstroms to about 2 microns.

FIG. 2 shows the results of dimensionally (i.e., both thickness and linewidth) decreasing the mask layer 16a to form a mask layer 16a′. The dimensional decrease is effected by exposure of the mask layer 16a to a charged particle beam 19a. The charged particle beam 16a may comprise a flood charged particle beam or a focused charged particle beam, but preferably a focused charged particle beam. The charged particle beam 19a may comprise, but is not limited to, an electron beam, an ion beam, a proton beam or another negatively or positively charged particle beam. Typically, the charged particle beam 19a when comprising an electron beam has an energy from about 100 to about 5000 eV and provides a charged particle flux (i.e., current density) from about 10 to about 100 amperes per square centimeter semiconductor substrate 10 area when dimensionally decreasing the mask layer 16a to form the mask layer 16a′. The mask layer 16a may be dimensionally decreased in linewidth by about 10 to about 100 angstroms to provide the mask layer 16a′ of linewidth from about 450 angstroms to about 2 microns.

Such a dimensional decrease of the mask layer 16a to form the mask layer 16a′ when using the electron beam 19a irradiation is typical when the mask layer 16a comprises a photoresist material that is exposed using 157 nm or 193 nm photoexposure radiation. However, the embodiment and the invention also contemplate that the mask layer 16a may also be dimensionally increased to form a mask layer 16a″ that is illustrated in phantom in FIG. 2. Such a broadening of the mask layer 16a to form the mask layer 16a″ may be expected under certain circumstances when the mask layer 16a comprises a photoresist material that may be photo exposed using 248 nm or 365 nm photoexposure radiation.

FIG. 3 shows the results of separately treating the mask layer 166b with a charged particle beam 19b and dimensionally decreasing the same to form a mask layer 16b′. The same considerations apply for the mask layers 16b/16b′ and the charged particle beam 19b as above described within the context of the mask layers 16a/16a′ and the charged particle beam 19a. As is illustrated in FIG. 3, thickness dimensions and linewidth dimensions of the mask layers 16a′ and 16b′ need not necessarily be the same and are typically not the same. Within is particular embodiment, dimensions of the mask layer 16b′ are further reduced in comparison with dimensions of the mask layer 16a′. The embodiment also contemplates widened dimensions of the mask layer 16b to provide a mask layer 16b′, whose dimensions are illustrated in phantom.

FIG. 4 shows the results of sequentially: (1) etching the gate electrode material layer 14 to form a plurality of gate electrodes 14a and 14b; and (2) etching the gate dielectric material layer 12 to form a plurality of gate dielectrics 12a and 12b. The foregoing sequential etching is effected using the mask layers 16a′ and 16b′ as etch mask layers. The etching may be effected using etch methods including but not limited to wet chemical etch methods and dry plasma etch methods. Dry plasma etch methods are generally preferred insofar as dry plasma etch methods provide generally straight and perpendicular sidewalls to the gate electrodes 14a and 14b, and die gate dielectrics 12a and 12b. Dry plasma etch methods will typically use chlorine containing etchant gas compositions for etching silicon containing semiconductor materials, and fluorine containing etchant gas compositions for etching silicon containing dielectric materials.

FIG. 5 shows the results of fabricating a first transistor T1 and a second transistor T2 while using, respectively, the gate electrode 14a and the gate electrode 14b as corresponding gate electrodes therein. The first transistor T1 and the second transistor T2 further include spacers 18 and source/drain regions 20, of which a central lying of the source/drain regions 20 is shared by the first transistor T1 and the second transistor T2.

The spacers 18 may comprise any of several spacer materials. Non-limiting examples include conductor spacer materials and dielectric spacer materials, with dielectric spacer materials being considerably more common. Typically the spacers 18 are formed using a blanket layer deposition and anisotropic etchback method.

The source/drain regions 20 are formed using a two step ion implantation method. A first step within the two step ion implantation method uses the gate electrodes 14a and 14b absent the spacers 18 as a mask to form extension regions that are located beneath the spacers 18. A second step within the two step method uses the gate electrodes 14a and 14b with the spacers 18 as a mask to form larger contact region portions of the source/drain regions 20 that incorporate extension region portions of the source/drain regions 20.

As is illustrated within the schematic cross-sectional diagram of FIG. 5, and since the mask layers 16a′ and 16b′ are formed with differing linewidths, the gate electrodes 14a and 14b within the transistors T1 and T2 are also formed with differing linewidths, as well as different channel widths therebeneath within the semiconductor substrate 10.

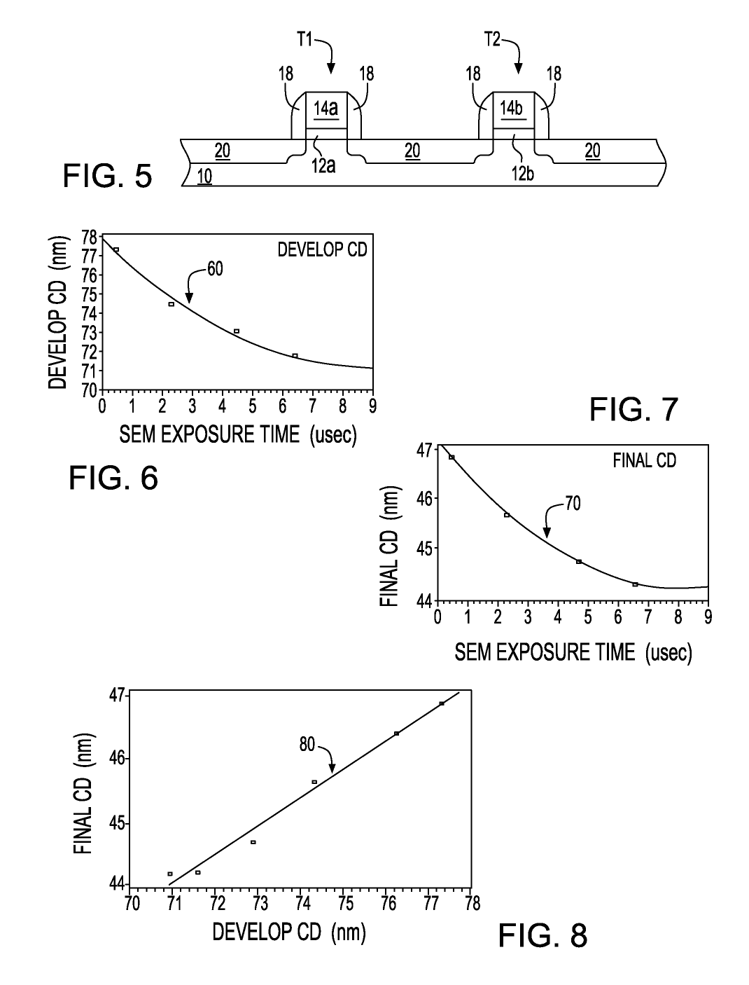

FIG. 6 shows a graph of Developed Critical Dimension (CD) versus Scanning Electron Microscope (SEM) Exposure Time for a 193 nm photoexposed patterned photoresist layer (i.e., having separated photoresist layer patterns) using an electron beam radiation at an energy of about 500 ev and a flux (i.e., current density) of about 100 amperes per square centimeter for the exposure time periods designated. The data points are fitted to a quadratic regression line 60.

FIG. 7 shows a graph of Final Critical Dimension (CD) versus Scanning Electron Microscope (SEM) Exposure Time for further etching a polysilicon gate electrode material layer located beneath the photoexposed patterned photoresist layer treated in accordance with the graph of FIG. 6. As is illustrated in FIG. 7 in comparison with FIG. 6, for a given SEM exposure time, a final CD of a gate electrode is significantly reduced in comparison with a developed CD of a patterned photoresist layer pattern that is used as an etch mask for forming the gate electrode. The data points of FIG. 7 are fitted to a quadratic regression line 70.

FIG. 8 shows a graph of Final Critical Dimension versus Developed Critical Dimension. The graph of FIG. 8 is derived from the graph of FIG. 6 and FIG. 7. The data points of FIG. 8 are fitted to a linear regression line 80.

The graphs of FIG. 6, FIG. 7 and FIG. 8 are intended to illustrate with particularity exemplary operability of the embodiment and the invention. The foregoing preferred embodiment is illustrative but not limiting of the invention. Revisions and modification to methods, materials, structures and dimensions of the preferred embodiment may yield additional embodiments of the invention, further in accordance with the accompanying claims.

What is claimed is:

1. A method for forming a patterned layer comprising:
providing a substrate having a blanket target layer located thereover and a mask layer located over the blanket target layer;
treating at least one individual mask layer pattern within the mask layer with a charged particle beam to form at least one dimensionally changed mask layer pattern within a dimensionally changed mask layer; and
etching the blanket target layer to form a patterned target layer while using the dimensionally changed mask layer as an etch mask.

2. The method of claim 1 wherein the treating the at least one individual mask layer pattern uses one of an electron beam and an ion beam as the charge particle beam.

3. The method of claim 1 wherein the treating the at least one individual mask layer pattern provides one of a dimensionally decreased mask layer pattern and a dimensionally increased mask layer pattern.

4. The method of claim 1 wherein the treating uses a focused charged particle beam.

5. The method of claim 1 wherein the treating uses a flood charged particle beam.

6. The method of claim 1 wherein the blanket target layer comprises a material selected from the group consisting of conductor materials, semiconductor materials and dielectric materials.

7. The method of claim 1 wherein the blanket target layer comprises a gate electrode material.

8. A method for forming a patterned layer comprising:
providing a substrate having a blanket target layer located thereover and a mask layer located over the blanket target layer;
treating separately at least two individual mask layer patterns within the mask layer with a focused charged particle beam to form at least two separate and differently dimensionally changed mask layer patterns within a dimension ally changed mask layer; and
etching the blanket target layer to form a patterned target layer while using the dimensionally changed mask layer as an etch mask.

9. The method of claim 8 wherein the treating the at least two individual mask layer patterns uses one of an electron beam and an ion beam as the charged particle beam.

10. The method of claim 8 wherein the treating the at least two individual mask layer patterns provides one of dimensionally decreased mask layer patterns and dimensionally increased mask layer patterns.

11. The method of claim 8 wherein the blanket target layer comprises a material selected from the group consisting of conductor materials, semiconductor materials and dielectric materials.

12. The method of claim 8 wherein the blanket target layer comprises a gate electrode material layer.
